(19) United States
(12) Patent Application Publication
(10) Pub. No.: US 2022/0157980 A1
(43) Pub. Date: May 19, 2022

(54) NITRIDE SEMICONDUCTOR DEVICE

(71) Applicant: PANASONIC CORPORATION, Osaka (JP)

(72) Inventors: Shinji UJITA, Osaka (JP); Satoshi TAMURA, Osaka (JP); Masahiro OGAWA, Osaka (JP); Daisuke SHIBATA, Kyoto (JP); Hiroyuki HANDA, Osaka (JP)

(21) Appl. No.: 17/428,741

(22) PCT Filed: Aug. 5, 2019
(86) PCT No.: PCT/JP2019/030768

§ 371 Date: Aug. 5, 2021

(30) Foreign Application Priority Data
Mar. 20, 2019 (JP) 2019-053451

(51) Int. Cl. H01L 29/778; H01L 29/20; H01L 29/66

(52) U.S. Cl. CPC H01L 29/7786; H01L 29/66462; H01L 29/2003

(57) ABSTRACT

A field-effect transistor includes a substrate having conductivity and made of gallium nitride, a buffer layer provided on the substrate and made of C-doped GaN, a drift layer provided on the buffer layer and made of undoped GaN, and a channel layer provided on the drift layer, made of undoped AlGaN, and joined to the drift layer by heterojunction. A gate electrode is provided on the channel layer. A source electrode and a drain electrode are each provided in regions on both sides of the gate electrode on the channel layer.

### TECHNICAL FIELD

The present disclosure relates to a nitride semiconductor apparatus.

### BACKGROUND ART

Typically, a power transistor using a group III nitride semiconductor has been used as a power semiconductor device. The group III nitride semiconductor is a compound semiconductor of at least one of group III elements, i.e., aluminum (Al), gallium (Ga), and indium (In), and nitrogen. Patent Document 1 and Patent Document 2 below describe a horizontal transistor configured such that a source electrode and a drain electrode are arranged on the same channel layer and made of a group III nitride semiconductor. This transistor is a normally-OFF field-effect transistor (FET) configured such that sapphire (single-crystal Al₂O₃) or silicon (Si) is used for a growth substrate and a hole injection layer made of p-type GaN is provided between a gate electrode and a channel layer therebelow.

Patent Document 3 below describes a GaN-based high electron mobility transistor (HEMT) which is also a horizontal device. Silicon is used for a growth substrate of this transistor. For example, in a case a channel layer is formed of a heterojunction made of an AlGaN/GaN layer, e.g., an undoped AlGaN layer having a greater bandgap than that of the GaN layer is, as a block layer, formed below the channel layer. Further, a superlattice structure is used as part of a buffer structure on the substrate, the superlattice structure having a heterojunction that aluminum gallium nitride (AlGaN) layers with different compositions are alternately stacked on each other. With this configuration, the GaN-based HEMT is configured such that a leakage current in a longitudinal direction is reduced and ON-resistance reduction and high-speed switching operation in a high-voltage region are achieved.

### CITATION LIST

### Patent Document

PATENT DOCUMENT 1: Japanese Patent No. 4712459 (FIG. 1, FIG. 4)
PATENT DOCUMENT 2: Japanese Patent No. 4705412 (FIG. 1)
PATENT DOCUMENT 3: U.S. Pat. No. 9,768,258 (FIG. 9)

### SUMMARY OF THE INVENTION

### Technical Problem

In recent years, study has been conducted on system voltage enhancement (about 800 V) for various purposes such as an in-vehicle power supply for an electric vehicle (EV), an uninterruptible power supply (UPS) for a data center, and a power conditioner. In the case of increasing the system voltage to 800 V as described above, a breakdown voltage of about 1200 V is required for the power transistor.

However, the above-described typical horizontal group III nitride field-effect transistor uses, as the growth substrate on which semiconductor layers (active layers) of the transistor are to be grown, a so-called hetero substrate having a different composition from that of any of the active layers. For this reason, it is difficult to increase the thickness of a buffer layer, including the superlattice structure, formed on the hetero substrate for achieving breakdown voltage enhancement.

For example, in the case of the silicon (Si) substrate as the hetero substrate, a dislocation density of about 10¹⁰ cm⁻² is caused in a gallium nitride layer forming the active layer, and a gallium nitride layer with a high crystallizability cannot be obtained. As a result, resistance reduction for bringing out the original potential of gallium nitride cannot be achieved.

Moreover, a lattice mismatch rate between silicon and gallium nitride is a high value of about 17%, and a lattice defect (a crack) is easily caused due to such a lattice mismatch rate difference and a difference in the coefficient of thermal expansion. For this reason, in the case of the field-effect transistor, it is, in some cases, configured such that the source electrode is connected to the substrate to reduce collapse current. In this case, a thickness in the longitudinal direction (a thickness direction of the semiconductor layer), specifically the thickness of the buffer layer, needs to be sufficiently great. However, the buffer layer on the inexpensive silicon hetero substrate can be deposited only with a thickness of about 5 μm to 6 μm, and it is difficult to increase a breakdown voltage in the longitudinal direction to 1000 V or higher.

The present disclosure is intended to solve the above-described typical problems and achieve breakdown voltage enhancement and ON-resistance reduction by improvement of the crystallizability of a nitride semiconductor layer on a buffer layer. An ON-resistance (Ron) indicates a resistance value between a drain and a source at the start of operation of a transistor.

### Solution to the Problem

For achieving the above-described object, the present disclosure is configured such that gallium nitride is used for a substrate for growth of a group III nitride semiconductor (hereinafter also referred to as a nitride semiconductor).

Specifically, the present disclosure is targeted for a nitride semiconductor apparatus, and takes the following technique as a solution.

That is, the present disclosure includes a substrate having conductivity and made of gallium nitride, a buffer layer provided on the substrate and made of a first group III nitride semiconductor, a drift layer provided on the buffer layer and made of a second group III nitride semiconductor, a channel layer provided on the drift layer, made of a third group III nitride semiconductor, and joined to the drift layer by heterojunction, a gate electrode provided on the channel layer, and a source electrode and a drain electrode each provided in regions on both sides of the gate electrode on the channel layer.

### Advantages of the Invention

According to the present disclosure, the buffer layer can be thickened to such an extent that required breakdown voltage enhancement can be achieved, and the crystallizability of the nitride semiconductor layer on the buffer layer is improved. Thus, the ON-resistance can be reduced.

### BRIEF DESCRIPTION OF THE DRAWINGS

FIG. 1 is a schematic sectional view showing a nitride semiconductor apparatus according to a first embodiment.

FIG. 2 is a graph for comparing a breakdown voltage between a GaN-based semiconductor device using gallium nitride for a substrate and a GaN-based semiconductor device using silicon for a substrate.

FIG. 3 is a schematic sectional view showing advantageous effects of an increase in the thickness of a buffer layer of the nitride semiconductor apparatus according to the first embodiment.

FIG. 4 is a table for comparing crystallizability between the GaN-based semiconductor using gallium nitride for the substrate and the GaN-based semiconductor using silicon for the substrate.

FIG. 5 is a graph for comparing Ron·Qoss in the GaN-based semiconductor device using gallium nitride for the substrate with Ron·Qoss in a silicon-based field-effect transistor and a silicon carbide-based field-effect transistor.

FIG. 6 is a schematic sectional view showing a nitride semiconductor apparatus according to a second embodiment.

### DESCRIPTION OF EMBODIMENTS

A first aspect according to one embodiment of the present disclosure includes a substrate having conductivity and made of gallium nitride, a buffer layer provided on the substrate and made of a first group III nitride semiconductor, a drift layer provided on the buffer layer and made of a second group III nitride semiconductor, a channel layer provided on the drift layer, made of a third group III nitride semiconductor, and joined to the drift layer by heterojunction, a gate electrode provided on the channel layer, and a source electrode and a drain electrode each provided in regions on both sides of the gate electrode on the channel layer.

According to this aspect, due to a homoepitaxial structure in which the buffer layer made of the first group III nitride semiconductor is provided on the substrate made of gallium nitride, there is no difference in lattice mismatch and no difference in the coefficient of thermal expansion. Thus, a defect such as a crack is less likely to occur, and the buffer layer can be thickened. Consequently, breakdown voltage enhancement can be achieved. In addition, due to the homoepitaxial configuration, a dislocation density is reduced as compared to the case of heteroepitaxial growth. Thus, the crystallizability of the nitride semiconductor layer on the buffer layer is improved. This increases an electron mobility in a two-dimensional electron gas (2DEG) layer formed at a hetero-interface between the drift layer made of the second group III nitride semiconductor and the channel layer made of the third group III nitride semiconductor. Thus, an ON-resistance can be reduced. As a result, a power loss upon operation can be reduced.

A second aspect may be that in the first aspect, the first group III nitride semiconductor has a dislocation density of equal to or lower than 5×10⁷ cm⁻².

According to this aspect, the substrate made of gallium nitride is used as a substrate for growth of the group III nitride semiconductor, and therefore, the dislocation density in the buffer layer grown on the substrate can be reduced to equal to or lower than 5×10⁷ cm⁻².

A third aspect may further include, in the first or second aspect, a p-type control layer provided between the channel layer and the gate electrode and made of a p-type fourth group III nitride semiconductor.

According to this aspect, the p-type control layer provided between the channel layer and the gate electrode is provided, and therefore, a band potential is lifted in a non-operation state in which no bias voltage is applied to the gate electrode. Thus, an electron carrier in the 2DEG layer below the gate electrode is depleted, and a normally-OFF state can be obtained. On the other hand, when a positive bias voltage is applied to the gate electrode, the band potential decreases, and therefore, the electron carrier is generated in the 2DEG layer below the gate electrode and drain-source current (Ids) flows.

A fourth aspect may be that in the first to third aspects, the buffer layer is doped with carbon (C), the thickness of the buffer layer is equal to or greater than 7 μm, and a doped carbon concentration is equal to or higher than 5×10¹⁷ cm⁻³.

According to this aspect, in a case where the buffer layer is doped with carbon with a concentration of 5×10¹⁷ cm⁻³, silicon (Si) and oxygen (O) entering from atmosphere, a manufacturing apparatus, etc. during manufacturing to bring an epitaxial layer into properties close to those of an n-type can be compensated. In addition, an energy level is formed in the band (the mid-gap) of gallium nitride forming the buffer layer. Electrons are trapped at the formed energy level in the mid-gap, and therefore, resistance enhancement in the buffer layer can be achieved, and a breakdown voltage can be improved by the buffer layer with a thickness of equal to or greater than 7 μm.

A fifth aspect may be that in the fourth aspect, the buffer layer contains at least one of silicon or oxygen and the carbon concentration of the buffer layer is higher than the sum of a silicon concentration and an oxygen concentration.

According to this aspect, in a case where the carbon concentration of the buffer layer is greater than the sum of the silicon concentration and the oxygen concentration, the polarity of the buffer layer becomes close to that of the n-type, and a decrease in the breakdown voltage of the buffer layer is suppressed. Moreover, the energy level in the mid-gap is formed due to the above-described carbon, and therefore, resistance enhancement in the buffer layer can be reliably achieved.

A sixth aspect may further include, in the first to fifth aspects, a breakdown voltage improvement layer provided between the buffer layer and the drift layer, joined to the drift layer by heterojunction, having a thickness of equal to or greater than 0.5 μm, and made of a fifth group III nitride semiconductor.

According to this aspect, breakdown voltage enhancement by an increase in the thickness of the channel layer results in a high concentration of the 2DEG layer, and therefore, normally-OFF properties are less likely to be obtained. Instead, the breakdown voltage improvement layer joined to the drift layer by heterojunction is provided between the buffer layer and the drift layer so that a breakdown voltage in a longitudinal direction can be higher.

A seventh aspect may be that in the sixth aspect, the breakdown voltage improvement layer is aluminum gallium nitride and an aluminum composition in the aluminum gallium nitride is equal to or higher than 1% and equal to or lower than 10%.

According to this aspect, the aluminum composition in the breakdown voltage improvement layer is lower than that of the channel layer. Thus, unintended formation of the 2DEG layer at an interface between the drift layer and the breakdown voltage improvement layer can be reduced and a gap in a lattice constant from that of the buffer layer made of GaN can be reduced.

An eighth aspect may further include, in the first to seventh aspects, a depletion layer formation layer provided between the substrate and the buffer layer and made of a p-type sixth group III nitride semiconductor.

According to this aspect, by the depletion layer formation layer provided between the substrate and the buffer layer, a high voltage is on the buffer layer and a ground voltage is on the depletion layer formation layer upon application of OFF-voltage. Thus, a deletion layer is formed at the buffer layer and the depletion layer formation layer, and therefore, the breakdown voltage in the longitudinal direction increases due to the formed depletion layer. Consequently, the breakdown voltage can be ensured by the formed depletion layer, and therefore, degradation of the yield of the breakdown voltage due to in-plane variation in the buffer layer can be reduced.

A ninth aspect may be that in the eighth aspect, the sixth group III nitride semiconductor is p-type gallium nitride and the thickness of the depletion layer formation layer is equal to or less than 500 nm. Note that in a case where a high voltage is applied to a buffer layer side to form a depletion layer between the depletion layer formation layer and the buffer layer, the thickness of the depletion layer formation layer is preferably designed such that no punch-through phenomenon occurs. As long as the above-described conditions are satisfied, the depletion layer formation layer is preferably formed as thin as possible.

Preferably, a tenth aspect is that in the first to ninth aspects, the source electrode is connected to the substrate.

With this configuration, a current collapse phenomenon can be reduced, and an increase in the ON-resistance can be prevented.

### First Embodiment

A first embodiment of the present disclosure will be described with reference to the drawings.

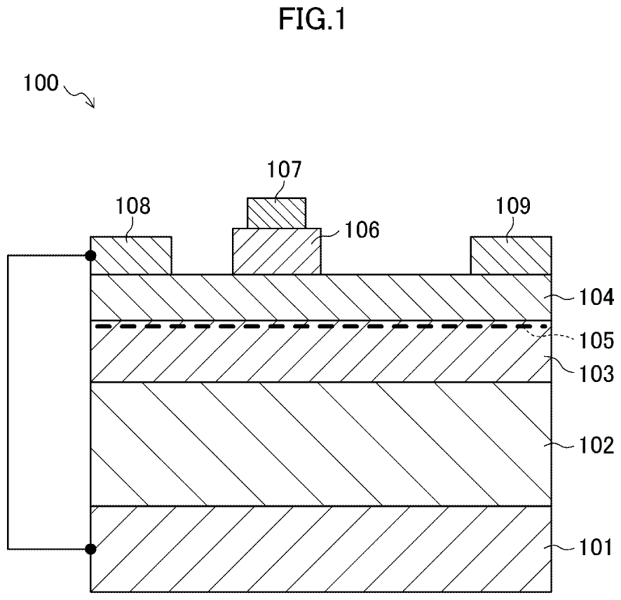

FIG. 1 shows a sectional configuration of a field-effect transistor 100 as one example of a nitride semiconductor apparatus according to the first embodiment. In this figure, the thickness of each semiconductor layer and the thickness and width of each electrode are not shown with actual dimensional ratios for the sake of convenience. The same also applies to the following configuration drawings.

As shown in FIG. 1, the field-effect transistor 100 has a buffer layer 102, a drift (electron transit) layer 103, a channel (electronic barrier) layer 104, and a p-type control layer 106 sequentially crystal-grown on a principal surface of a single-crystal substrate (hereinafter referred to as a substrate) 101 having conductivity, made of gallium nitride (GaN), and provided for device growth. The buffer layer 102 is, for example, made of carbon-doped (C-doped) gallium nitride (i-GaN). The drift layer 103 is, for example, made of undoped gallium nitride (i-GaN). The channel layer 104 is, for example, made of undoped aluminum gallium nitride (i-AlGaN). The p-type control layer 106 is, for example, made of p-type gallium nitride (p-GaN) selectively formed on the channel layer 104. Note that “undoped” means a state in which a semiconductor as a target is not doped with an impurity actively, i.e., purposely.

For example, a surface with a plane orientation (0001), i.e., a c-surface, can be used as the principal surface of the substrate 101. For example, an n-type GaN substrate having a thickness of about 300 μm and doped with silicon (Si) as a donor may be used as the substrate 101. Note that the conductivity of the substrate 101 may be of a p-type. For example, magnesium (Mg) can be used as an acceptor in this case.

The buffer layer 102 is, for example, i-GaN having a thickness of 10 μm and doped with carbon (C) in a concentration of equal to or higher than 5×10¹⁷ cm⁻³. Note that it may only be required that the thickness of the buffer layer 102 is equal to or greater than 7 μm. Note that on the assumption that the concentrations of silicon (Si) and Oxygen (O) entering from atmosphere, a manufacturing apparatus (tool), etc. during manufacturing are each 2×10¹⁵ cm⁻³ and 6×10¹⁵ cm⁻³, a carbon concentration is set higher than the sum of the silicon concentration and the oxygen concentration such that doped carbon is not fully compensated by silicon and oxygen. As described above, due to doped carbon, an energy level is formed in the mid-gap of GaN forming the buffer layer 102. Electrons are trapped at the formed level in the mid-gap. Thus, enhancement of the resistance of the buffer layer 102 can be achieved, and a breakdown voltage can be improved.

The buffer layer 102 made of C-doped i-GaN according to the present embodiment is crystal-grown on the principal surface of the substrate 101 made of n-GaN, and even in the case of a thickness of 10 μm, the dislocation density thereof can be suppressed to equal to or lower than 5×10⁷ cm⁻². Normally, the dislocation density of the nitride semiconductor crystal-grown on the principal surface of the substrate 101 made of GaN is suppressed to about 5×10⁶ cm⁻². As one example of a first group III nitride semiconductor, i-GaN forming the buffer layer 102 is conceivable. Thus, i-GaN may be, within such a range that a difference in a lattice mismatch rate between i-GaN and the substrate 101 is not relatively great, C-doped i-AlGaN, C-doped i-AlInGaN, or C-doped i-InGaN. Note that GaN is preferably used for the buffer layer 102 because GaN is used for the 101.

The drift layer 103 is, for example, i-GaN with a thickness of about 500 nm. As one example of a second group III nitride semiconductor, i-GaN forming the drift layer 103 is conceivable. Thus, i-GaN may be, within such a range that a difference in a lattice mismatch rate between i-GaN and the buffer layer 102 is not relatively great, i-AlGaN, i-AlInGaN, i-InGaN, or i-InN.

The channel layer 104 joined to the drift layer 103 by heterojunction is, for example, i-AlGaN with a thickness of about 25 nm. An Al composition in i-AlGaN is 0.2, for example. Note that it may only be required that the Al composition is equal to or higher than 0.1 and equal to or lower than 0.5. As publicly known, the bandgap of an AlGaN semiconductor is greater than the bandgap of a GaN semiconductor. As one example of a third group III nitride semiconductor, i-AlGaN forming the channel layer 104 is conceivable. Thus, i-AlGaN may be i-AlInGaN or i-AlN within such a range that the bandgap is greater than that of the drift layer 103 and a difference in a lattice mismatch rate between i-AlGaN and the drift layer 103 is not too great.

As described above, the channel layer 104 and the drift layer 103 are joined to each other by heterojunction, the channel layer 104 having a greater bandgap than that of the drift layer 103. As described above, at an interface between both semiconductor layers, a two-dimensional electron gas (2DEG) layer 105 is generated by spontaneous polarization and piezoelectric polarization due to the group III nitride semiconductors.

The p-type control layer 106 is, for example, p-GaN with a thickness of about 100 nm. The concentration of magnesium (Mg) as a p-type impurity is about 1×10¹⁹ cm⁻³, for example. As one example of a fourth group III nitride semiconductor, p-GaN forming the p-type control layer 106 is conceivable. Thus, p-GaN may be, within such a range that a difference in a lattice mismatch rate between p-GaN and the channel layer 104 is not relatively great, p-AlN, p-AlGaN, p-AlInGaN, or p-InGaN.

A gate electrode 107 is provided on the p-type control layer 106. In regions on both sides of the p-type control layer 106 on the channel layer 104, a source electrode 108 and a drain electrode 109 are provided.

For example, a single-layer film made of palladium (Pd) or a multilayer film of palladium (Pd) and gold (Au) can be used for the gate electrode 107, the single-layer film and the multilayer film having a thickness of about 100 nm. For example, a multilayer film of titanium (Ti) and aluminum (Al) having a stack thickness of about 100 nm can be used for the source electrode 108 and the drain electrode 109. An interval between the gate electrode 107 and the drain electrode 109 is set greater than an interval between the gate electrode 107 and the source electrode 108. With this configuration, the breakdown voltages (breakdown voltages in a traverse direction) of the gate electrode 107 and the drain electrode 109 are enhanced.

Moreover, the source electrode 108 is electrically connected to the substrate 101. This reduces a current collapse phenomenon and prevents an increase in an ON-resistance. Note that as publicly known, the current collapse phenomenon means a phenomenon in which electrons accelerated due to concentration of a high electrical field in a traverse direction are trapped at a deep level due to a defect at an interface with an insulator or in a semiconductor and a channel is partially depleted and a drain current decreases due to failure in quick recovery. The current collapse phenomenon is one cause for an increase in the ON-resistance. Due to connection of the source electrode 108 to the substrate 101, the electrical field is also spread in a longitudinal direction, and electrical field concentration is relaxed. Thus, the current collapse phenomenon can be reduced. On the other hand, due to connection between the source electrode 108 and the substrate 101, a breakdown voltage (a breakdown voltage in the longitudinal direction) needs to be increased in a direction in which the source electrode 108 and the substrate 101 face each other. Note that in the case of employing a configuration in which the source electrode 108 is not connected, the substrate 101 does not necessarily have the conductivity.

In the present specification, “provided on the principal surface of the substrate 101” may be, for example, the state of direct contact with the principal surface of the substrate 101 or the state of indirect contact with the principal surface of the substrate 101 through, e.g., other semiconductor layers. Note that in the case of the direct contact, description such as “provided directly on the principal surface” will be made. The same also applies to the case of description “below the buffer layer 102,” for example.

(Operation of Field-Effect Transistor)

In the field-effect transistor 100, in a case where no gate bias (no gate voltage) is applied, a potential barrier increases due to substantial pn junction between the p-type control layer 106 and the channel layer 104 therebelow. Thus, a normally-OFF state is achieved. Further, improvement of an ON-voltage in a gate forward direction and reduction in a gate leakage current are achieved.

Next, when a gate bias is applied with a voltage of equal to or lower than a voltage in the forward direction of the above-described pn junction, the potential barrier in the channel layer 104 decreases. After the gate bias has reached a value of equal to or greater than a threshold of the field-effect transistor, current starts flowing.

Next, after the gate bias has exceeded the voltage in the forward direction, hole injection from the p-type control layer 106 into the 2DEG layer 105 starts. For satisfying charge neutral conditions, the same amount of electrons as that of the injected holes is drawn out of the source electrode 108 into the 2DEG layer 105 (the drift layer 103). Accordingly, the drawn electrons move toward the drain electrode 109 by drain voltage. At this point, the mobility of the holes injected into the drift layer 103 is lower than that of the electrons by about double digits, and therefore, these holes are accumulated below the gate electrode 107. In addition, almost no hole flows into the gate electrode 107 due to the potential barrier by the heterojunction between the drift layer 103 and the channel layer 104.

### Advantageous Effects

(1) Improvement of Breakdown Voltage

In the present embodiment, the substrate 101 made of single-silicon GaN is used as a substrate for growth of a group III nitride semiconductor (hereinafter also referred to as a GaN-based semiconductor), taking a field-effect transistor which is a horizontal device as an example. Thus, the buffer layer 102 homoepitaxially grown on the principal surface of the substrate 101 and made of GaN has almost no difference in lattice mismatch and no difference in the coefficient of thermal expansion. Consequently, almost no defect such as a crack is caused. With this configuration, the thickness of the buffer layer 102 can be increased to equal to or greater than 7 μm, and as a result, the breakdown voltage in the longitudinal direction is improved.

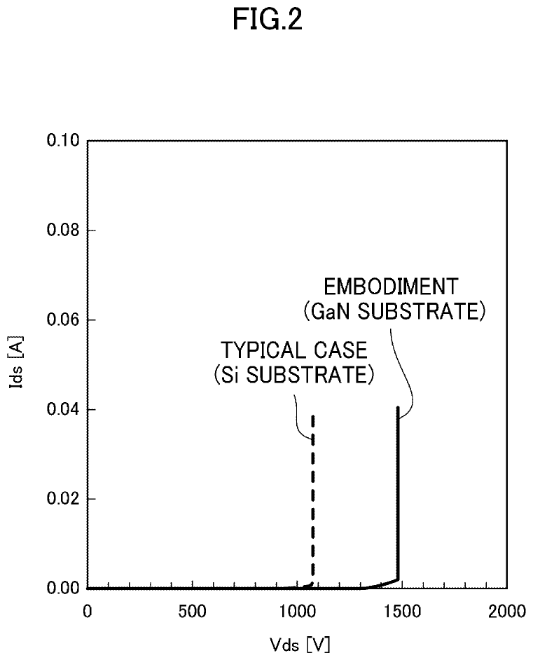

FIG. 2 shows, as one example, comparison between the breakdown voltage of a GaN-based semiconductor device (a field-effect transistor) using gallium nitride (GaN) for the growth substrate according to the present embodiment and the breakdown voltage of a typical GaN-based semiconductor device (a field-effect transistor) using silicon (Si) for a growth substrate. As shown in FIG. 2, in the case of using the typical Si substrate, a drain-source voltage Vds indicated by the horizontal axis shows about 1080 V when a drain-source current Ids indicated by the vertical axis is 0.04 A. On the other hand, in the case of using the GaN substrate of the present embodiment, the drain-source voltage Vds shows about 1500 V when the drain-source current Ids is an identical value of 0.04 A, and about a 1.4-fold breakdown voltage is obtained.

(2) Reduction in Output Capacitance Coss

In the present embodiment, an output capacitance Coss in the capacitance (the parasitic capacitance) of the field-effect transistor 100 can be reduced due to an increase in the thickness of the buffer layer 102. With this configuration, the drain-source voltage Vds upon soft switching can be switched to 0 V at a high speed.

The output capacitance Coss is represented by Formula (1) below.

Coss=Cds+Cdg (1)

where Cds represents a drain-source inter-electrode capacitance and Cdg represents a drain-gate inter-electrode capacitance.

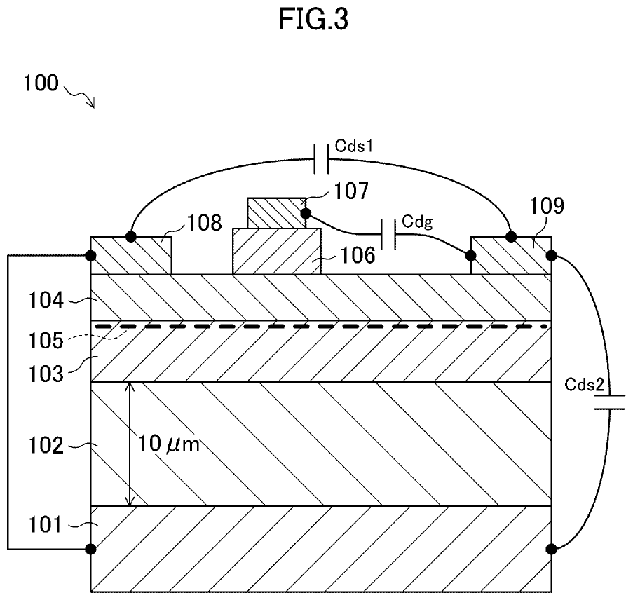

As shown in FIG. 3, the field-effect transistor 100 is configured such that the source electrode 108 is connected to the substrate 101, and therefore, Cds is represented by Formula (2) below.

Cds=Cds1+Cds2 (2)

In the present embodiment, the thickness of the buffer layer 102 is increased to 10 μm. For example, when the thickness of a typical buffer layer is 5 μm, Capacitance Simple Calculation Formula (3) is as follows:

C=ε×S/d (3)

where ε represents a substance permittivity, S represents an electrode area, and d represents an inter-electrode distance.

The capacitance value of Cds2 can be reduced to the half of the capacitance of the typical transistor, and therefore, the output capacitance Coss can be reduced due to an increase in the thickness of the buffer layer 102.

(3) Improvement of Crystallizability

Moreover, in the field-effect transistor 100 according to the present embodiment, the dislocation density of the GaN buffer layer crystal-grown on the principal surface of the single-crystal GaN substrate 101 can be reduced to equal to or lower than 5×10⁷ cm⁻², such as 5×10⁶ cm⁻². With this configuration, the thickness of the buffer layer 102 can be increased to equal to or greater than 7 μm, and as a result, the breakdown voltage in the longitudinal direction is improved.

Note that it has been known that by using silicon (Si) for the growth substrate, the dislocation density of the buffer layer provided on such a substrate and made of GaN is equal to or higher than 1×10¹⁰ cm⁻². Moreover, it has been known that by using sapphire (single-crystal Al₂O₃) for the growth substrate, the dislocation density of the buffer layer made of GaN is 1×10⁸ cm⁻².

For measuring the dislocation density of a semiconductor crystal, the following two methods are conceivable.

As the first method, a transmission electron microscope (TEM) is used in the case of a relatively-high dislocation density. A sample is cut out in a spot shape from a semiconductor targeted for measurement, and the number of streak-shaped portions as dislocations is counted from the side of the cut sample. In this case, a measurement area is small, and a burden upon counting is relatively small.

As the second method, a cathodoluminescence measurement method is used in the case of a relatively-low dislocation density, such as the case of a dislocation density of equal to or lower than 5×10⁷ cm⁻² as in the present embodiment. In this measurement method, the number of dark spots is counted. There are advantages that the dislocation density can be measured across a wide area and non-destructive measurement can be performed.

Due to reduction in the dislocation density of the buffer layer 102, favorable crystallizability of each GaN-based semiconductor layer including the drift layer 103 crystal-grown on the buffer layer 102 and made of at least undoped GaN and the channel layer 104 made of undoped AlGaN is achieved. Thus, an electron mobility in the drift layer 103 and the channel layer 104 is, including the 2DEG layer 105, maintained high, and therefore, reduction in the ON-resistance is achieved.

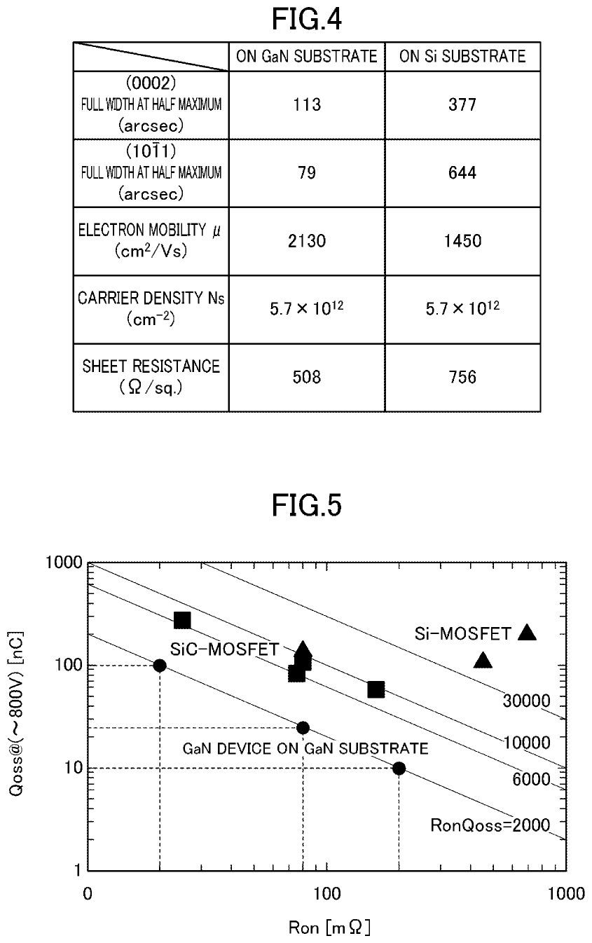

FIG. 4 shows one example of various parameters indicating the quality, i.e., the crystallizability, of the GaN-based semiconductor using GaN for the growth substrate in the present embodiment and the GaN-based semiconductor using silicon (Si) for the growth substrate. As shown in FIG. 4, in terms of a full width at half maximum (FWHM) in a rocking curve in X-ray diffraction (XRD), a measurement value decreases, in the case of reflection on a surface with a plane orientation (0002) (tilt distribution), to about 30% in the GaN-based semiconductor on the GaN substrate as compared to the GaN-based semiconductor on the Si substrate. That is, the tilt distribution shows sharp favorable distribution. In the case of reflection on a surface with a plane orientation (10-11) (twist distribution), the measurement value decreases to about 12% in the GaN-based semiconductor on the GaN substrate as compared to the GaN-based semiconductor on the Si substrate. That is, sharp favorable distribution is also shown in the twist distribution. Note that a negative sign “−” in the index of the plane orientation indicates, for the sake of convenience, inversion of an index subsequent to the negative sign.

In terms of the electron mobility, the mobility in the case of using the GaN substrate increases to about 1.5 times as compared to the case of using the Si substrate. Note that the dislocation density in the GaN-based semiconductor on the GaN substrate at this point is 5×10⁶ cm⁻² as described above, and the dislocation density in the GaN-based semiconductor on the Si substrate is 1×10¹⁰ cm⁻² as described above. Although not shown in FIG. 4, the electron mobility in the GaN-based semiconductor on the sapphire substrate is 1700 cm²/Vs, and the dislocation density in the GaN-based semiconductor at this point is 1×10⁸ cm⁻².

A sheet resistance also decreases by about 33% in the case of the GaN-based semiconductor on the GaN substrate as compared to the case of the Si substrate.

Note that in a case where the crystal dislocation density is high in the drift layer 103 and the channel layer 104, a trap is formed at the interface between the drift layer 103 and the channel layer 104 generating the 2DEG layer 105, and electrons are trapped by such a trap. When the electrons are trapped by the trap, a band potential is lifted to form a barrier to electron transit. Moreover, the moving electrons are also scattered by spots negatively charged due to trapping of the electrons by the trap. Due to these factors, the electron mobility decreases, and the ON-resistance increases.

(4) Reduction in Ron·Qoss

It has been known that in a transistor device, a smaller product (Ron·Qoss) of an ON-resistance Ron and an output charge capacity Qoss is more advantageous in high-frequency drive. The output charge capacity Qoss is a charge amount between the drain and the source, and indicates the amount of charge accumulated on the above-described output capacitance Coss.

The output charge capacity Qoss is an important parameter in soft switching necessary for performing the high-frequency drive for system size reduction. Particularly, a low Qoss is necessary for the so-called zero voltage switching (ZVS) operation of performing such control that a gate voltage is turned on to start the flow of the drain-source current Ids after the value of the drain-source voltage Vds has fallen to 0 V. When such operation is performed, a switching loss upon turn-on can be almost zero. On the other hand, in the case of a transistor with a high output charge capacity Qoss, a speed at which the value of the drain-source voltage Vds falls to 0 V decreases, and therefore, the high-frequency drive cannot be achieved. Thus, a low Qoss is necessary for the high-frequency drive of the system.

FIG. 5 shows, in terms of Ron·Qoss, comparison of the GaN-based semiconductor transistor using GaN for the growth substrate in the present embodiment with a Si-based field-effect transistor (metal-oxide-semiconductor field-effect transistor: MOSFET) and a SiC-based (silicon carbide-based) field-effect transistor (MOSFET).

In FIG. 5, the vertical axis on the left side indicates the output charge capacity Qoss (nC) up to a drain voltage of 800 V, the horizontal axis indicates the ON-resistance Ron (mΩ), solid lines in a graph indicate values obtained by multiplication of Ron and Qoss. For example, the solid line at the minimum level indicates 2000 in terms of the product Ron·Qoss, and the solid line at the maximum level indicates 30000 in terms of the product Ron·Qoss.

As seen from FIG. 5, in one example of the case (a black circle mark) of the GaN-based semiconductor transistor on the GaN substrate according to the present embodiment, Ron is 80 mΩ, Qoss is 25 nC, and the product thereof is 2000.

On the other hand, the value of Ron·Qoss in the case (a black triangular mark) of the Si-based field-effect transistor is equal to or greater than approximately 9000. Even in the case (a black rectangular mark) of the SiC-based field-effect transistor, the value of Ron·Qoss is equal to or greater than about 6000 and equal to or less than 9000.

### Second Embodiment

Hereinafter, a second embodiment of the present disclosure will be described with reference to the drawings.

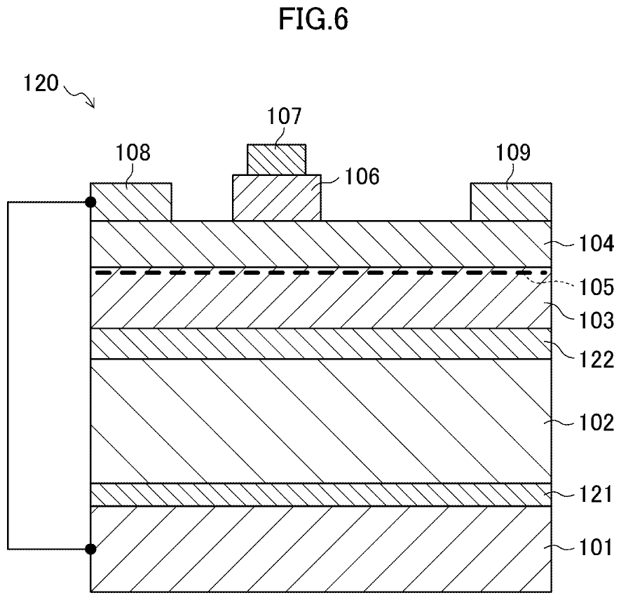

FIG. 6 shows a sectional configuration of a field-effect transistor 120 as one example of a nitride semiconductor apparatus according to the second embodiment.

The field-effect transistor 120 according to the second embodiment has a configuration capable of further improving a breakdown voltage as compared to the field-effect transistor 100 according to the first embodiment. Note that in FIG. 6, the same reference numerals are used to represent the same components as those shown in FIG. 1, and therefore, description thereof will be omitted.

As shown in FIG. 6, a depletion layer formation layer 121 made of p-type gallium nitride (p-GaN) is, for example, provided between a substrate 101 and a buffer layer 102. The thickness of the depletion layer formation layer 121 is 200 nm, for example. Note that it may only be required that the thickness of the depletion layer formation layer 121 is equal to or less than about 500 nm. Note that p-GaN forming the depletion layer formation layer 121 is one example of a sixth group III nitride semiconductor. Thus, p-GaN may be, within such a range that a difference in a lattice mismatch rate between p-GaN and the substrate 101 is not relatively great, p-AlN, p-AlGaN, p-AlInGaN, or p-InGaN. Note that the substrate 101 is GaN, and therefore, p-GaN is preferred for the depletion layer formation layer 121.

Moreover, a breakdown voltage improvement layer 122 made of undoped aluminum gallium nitride (i-AlGaN) is, for example, provided between the buffer layer 102 and a drift layer 103. An Al composition in the breakdown voltage improvement layer 122 is 0.05, for example. The thickness of the breakdown voltage improvement layer 122 is 1 μm, for example. Note that it may only be required that the Al composition of the breakdown voltage improvement layer 122 is equal to or higher than 0.01 and equal to or lower than 0.1 and the thickness of the breakdown voltage improvement layer 122 is equal to or greater than 500 nm. Note that i-AlGaN forming the breakdown voltage improvement layer 122 is one example of a fifth group III nitride semiconductor. Thus, i-AlGaN may be, within such a range that a difference in a lattice mismatch rate between i-AlGaN and the buffer layer 102 is not relatively great, i-AlN, i-AlInGaN, or i-InGaN. Note that i-AlGaN with the same mixed crystal as that of a channel layer 104 is preferably used for the breakdown voltage improvement layer 122 even though a composition ratio is different.

Note that in the present embodiment, only either one of the depletion layer formation layer 121 or the breakdown voltage improvement layer 122 may be provided. In the case of providing both of the depletion layer formation layer 121 and the breakdown voltage improvement layer 122, the breakdown voltage is improved by about 50% as compared to the field-effect transistor 100 according to the first embodiment, and yield degradation due to in-plane variation can be reduced by about 30%.

As described above, the depletion layer formation layer 121 made of p-type GaN is provided between the n-type GaN substrate 101 and the buffer layer 102. Thus, upon application of OFF-voltage, a high voltage is on the buffer layer 102, and a ground voltage is on the depletion layer formation layer 121. Thus, a deletion layer is formed at the buffer layer 102 and the depletion layer formation layer 121, and therefore, a breakdown voltage in a longitudinal direction increases due to the formed depletion layer. Note that the thickness of the depletion layer formation layer 121 is not limited to 200 nm, and may be equal to or greater than 100 nm and equal to or less than 500 nm.

Moreover, in the present embodiment, the breakdown voltage improvement layer 122 made of i-AlGaN is provided between the buffer layer 102 made of GaN and the drift layer 103 made of i-GaN. This is because the concentration of a 2DEG layer 105 becomes too high and normally-OFF properties are less likely to be obtained when an attempt is made to increase the breakdown voltage by an increase in the thickness of the channel layer 104. Thus, the breakdown voltage improvement layer 122 joined to a lower surface of the drift layer 103 by heterojunction is provided between the buffer layer 102 and the drift layer 103, and therefore, the breakdown voltage in the longitudinal direction can be more increased.

Note that the Al composition of i-AlGaN forming the breakdown voltage improvement layer 122 is set lower than that of the channel layer 104 made of i-AlGaN. This is preferred because unintended formation of the 2DEG layer at an interface between the drift layer 103 and the breakdown voltage improvement layer 122 can be reduced and a gap in a lattice constant from that of the buffer layer 102 made of GaN can be reduced.

(Manufacturing Method)

Hereinafter, one example of the method for manufacturing the field-effect transistor 120 according to the second embodiment will be described.

First, a substrate 101 having a surface with a plane orientation (0001), i.e., a c-surface, as a principal surface and made of n-type GaN is prepared.

For example, as the film formation method for forming a GaN-based semiconductor layer on the principal surface of the substrate 101, a metalorganic vapor phase epitaxy (MOVPE) method can be used. For example, as other film formation methods, a molecular beam epitaxy (MBE) method can be used.

An n-type GaN-based semiconductor can be formed by addition of silicon (Si), for example. A p-type GaN-based semiconductor can be formed by addition of magnesium (Mg). Note that an n-type impurity and a p-type impurity are not limited to above.

Next, by the MOVPE method, a depletion layer formation layer 121 made of p-GaN to which Mg has been added as the p-type impurity is grown on the principal surface of the substrate 101 at a growth temperature of 950° C. The composition, thickness, and impurity concentration of each GaN-based semiconductor layer are the same as those of the second embodiment.

As various manufacturing parameters for the depletion layer formation layer 121, the flow rate of ammonia (NH₃) as a group V source is 40 L/min (a standard state (0° C., 1 atm): the same flow rate applies below), and the flow rate of trimethyl gallium (TMG) as a group III source is 16 mL/min. The value of a V/III ratio indicating a molar ratio between the group V source and the group III source is 10000. Moreover, the flow rate of hydrogen (H₂) is 32 L/min and the flow rate of nitrogen (N₂) is 46 L/min, both of hydrogen and nitrogen being carrier gas. The same flow rate of ammonia (NH₃) and the same flow rate of the carrier gas also apply to a GaN-based semiconductor below.

Next, a buffer layer 102 made of i-GaN is grown on the depletion layer formation layer 121 at a growth temperature of 1020° C. Due to influence of a manufacturing apparatus or tool etc., silicon (Si) and oxygen (O) might be, as impurities, taken into the buffer layer 102 at this point, and the buffer layer 102 might exhibit conductivity close to that of the n-type. For compensating for these unintended impurities, carbon (C) is added as an impurity. A carbon concentration at this point is, as described above, higher than the sum of a silicon concentration and an oxygen concentration. Note that the carbon concentration can be increased by a decrease in the growth temperature of the buffer layer 102 or an increase in the growth speed of the buffer layer 102. As manufacturing parameters for the buffer layer 102, the flow rate of TMG as the group III source is 100 mL/min. The value of the V/III ratio is 1000. At this point, the growth temperature relating to the flow rate of TMG as a raw material and the uptake amount of a methyl group CH₃ in TMG is adjusted such that the carbon concentration of the buffer layer 102 is equal to or higher than 5×10¹⁷ cm⁻³.

Next, a breakdown voltage improvement layer 122 made of i-Al_{0.05}Ga_{0.95}N is grown on the buffer layer 102 at a growth temperature of 1100° C. As manufacturing parameters for the breakdown voltage improvement layer 122, the flow rate of TMG as the group III source is 38 mL/min, and the flow rate of trimethyl aluminium (TMA) is 7 mL/min. The value of the V/III ratio is 4000.

Next, a drift layer 103 made of i-GaN is grown on the breakdown voltage improvement layer 122 at a growth temperature of 1020° C. As manufacturing parameters for the drift layer 103, the flow rate of TMG as the group III source is 38 mL/min. The value of the V/III ratio is 4000.

Next, a channel layer 104 made of i-Al_{0.2}Ga_{0.8}N is grown on the drift layer 103 at a growth temperature of 1100° C. As manufacturing parameters for the channel layer 104, the flow rates of TMG and TMA as the group III sources are both 5 mL/min. The value of the V/III ratio is 25000.

Next, a p-type control layer 106 made of p-GaN to which Mg has been added as a p-type impurity is grown on the entire surface of the channel layer 104 at a growth temperature of 950° C. As manufacturing parameters for the p-type control layer 106, the flow rate of TMG as the group III source is 100 mL/min. The value of the V/III ratio is 1000.

Note that although the temperature and the flow rate of the raw material gas are changed as necessary, the steps are executed as a series of growth steps from the buffer layer 102 on the substrate 101 to the p-type control layer 106.

Next, the substrate 101 on which the layers up to the p-type control layer 106 are formed is taken out of the MOVPE apparatus. Subsequently, a resist is applied to the entire surface of the p-type control layer 106, and the applied resist is patterned by photolithography such that a portion including a region where a gate electrode 107 is to be formed remains. Accordingly, a resist mask for patterning the p-type control layer 106 is formed. Dry etching is performed using this resist mask, and in this manner, the desired p-type control layer 106 is formed and the channel layer 104 is exposed on both sides of the p-type control layer 106.

Next, by, e.g., a vacuum deposition method or a sputtering method, a multilayer film of Ti and Al is formed on the exposed channel layer 104 across the entire surface including the patterned p-type control layer 106. Subsequently, a source electrode 108 and a drain electrode 109 formed from the multilayer film of Ti and Al are formed in such a manner that the formed multilayer film is patterned in a desired manner by means of a resist. Subsequently, sintering is performed within a temperature range of 450° C. to 550° C. such that the source electrode 108 and the drain electrode 109 come into ohmic contact with the channel layer 104 made of i-AlGaN and a contact resistance decreases accordingly.

Next, by the vacuum deposition method or the sputtering method, a gate metal film as a Pd single-layer film or a multilayer film of Pd and Au is formed again on the channel layer 104 across the entire surface including the patterned p-type control layer 106. Subsequently, the formed gate metal film is patterned in a desired manner by photolithography, and in this manner, the gate electrode 107 is formed from the gate metal film. The compositions and thicknesses of the source electrode 108, the drain electrode 109, and the gate electrode 107 are the same as those of the second embodiment.

Note that at each step of forming the source electrode 108 and the drain electrode 109 and forming the gate electrode 107, the desired resist pattern is formed on the metal film after the metal film for electrode formation has been formed. Instead of this method, a so-called lift-off method may be used. In the lift-off method, a resist film is first formed as a mask pattern masking a region other than an electrode pattern, and thereafter, a predetermined metal film is deposited on the entire surface including the formed mask pattern and the mask pattern is further removed together with the metal film deposited on the mask pattern.

By the above-described steps, the field-effect transistor 120 shown in FIG. 6 is formed.

The method for manufacturing the field-effect transistor 120 according to the second embodiment has been described herein, but the method for manufacturing the field-effect transistor 100 according to the first embodiment is the same as that for the field-effect transistor 120, except that each step of growing the depletion layer formation layer 121 below the substrate 101 and the breakdown voltage improvement layer 122 on the substrate 101 in the field-effect transistor 120 is omitted.

### Other Embodiments

In the first embodiment and the second embodiment, the field-effect transistor (FET) achieving normally-OFF operation and having the p-type control layer fulfilling the function of injecting the holes to the 2DEG layer has been described as an example of the nitride semiconductor apparatus, but the present disclosure is not limited to this configuration. That is, the present disclosure mainly aims to achieve breakdown voltage enhancement and ON-resistance reduction (speed-up), and for a nitride semiconductor apparatus configured without a p-type control layer, breakdown voltage enhancement and ON-resistance reduction can be also achieved.

### INDUSTRIAL APPLICABILITY

The nitride semiconductor apparatus according to the present disclosure is useful as a power semiconductor device aiming to achieve breakdown voltage enhancement and ON-resistance reduction.

### DESCRIPTION OF REFERENCE CHARACTERS

100, 120 Field-Effect Transistor
101 Substrate
102 Buffer Layer
103 Drift Layer
104 Channel Layer
105 2DEG Layer
106 p-Type Control Layer
107 Gate Electrode
108 Source Electrode
109 Drain Electrode
121 Depletion Layer Formation Layer
122 Breakdown Voltage Improvement Layer

1. A nitride semiconductor apparatus comprising:
a substrate having conductivity and made of gallium nitride;
a buffer layer provided on the substrate and made of a first group III nitride semiconductor;
a drift layer provided on the buffer layer and made of a second group III nitride semiconductor;
a channel layer provided on the drift layer, made of a third group III nitride semiconductor, and joined to the drift layer by heterojunction;
a gate electrode provided on the channel layer; and
a source electrode and a drain electrode each provided in regions on both sides of the gate electrode on the channel layer.

2. The nitride semiconductor apparatus according to claim 1, wherein
the first group III nitride semiconductor has a dislocation density of equal to or lower than 5×10⁷ cm⁻².

3. The nitride semiconductor apparatus according to claim 1, further comprising:
a p-type control layer provided between the channel layer and the gate electrode and made of a p-type fourth group III nitride semiconductor.

4. The nitride semiconductor apparatus according to claim 1, wherein
the buffer layer is doped with carbon, and
a thickness of the buffer layer is equal to or greater than 7 μm, and a doped carbon concentration is equal to or higher than 5×10¹⁷ cm⁻³.

5. The nitride semiconductor apparatus according to claim 4, wherein
the buffer layer contains at least one of silicon or oxygen, and
the carbon concentration of the buffer layer is higher than a sum of a silicon concentration and an oxygen concentration.

6. The nitride semiconductor apparatus according to claim 1, further comprising:
a breakdown voltage improvement layer provided between the buffer layer and the drift layer, joined to the drift layer by heterojunction, having a thickness of equal to or greater than 0.5 μm, and made of a fifth group III nitride semiconductor.

7. The nitride semiconductor apparatus according to claim 6, wherein
the fifth group III nitride semiconductor is aluminum gallium nitride, and
an aluminum composition in the aluminum gallium nitride is equal to or higher than 1% and equal to or lower than 10%.

8. The nitride semiconductor apparatus according to claim 1, further comprising:
a depletion layer formation layer provided between the substrate and the buffer layer and made of a p-type sixth group III nitride semiconductor.

9. The nitride semiconductor apparatus according to claim 8, wherein
the sixth group III nitride semiconductor is p-type gallium nitride, and
a thickness of the depletion layer formation layer is equal to or less than 500 nm.

10. The nitride semiconductor apparatus according to claim 1, wherein
the source electrode is connected to the substrate.

11. The nitride semiconductor apparatus according to claim 2, further comprising:
a p-type control layer provided between the channel layer and the gate electrode and made of a p-type fourth group III nitride semiconductor.

12. The nitride semiconductor apparatus according to any one of claim 2, wherein
the buffer layer is doped with carbon, and
a thickness of the buffer layer is equal to or greater than 7 μm, and a doped carbon concentration is equal to or higher than 5×10¹⁷ cm⁻³.

13. The nitride semiconductor apparatus according to any of claim 2, further comprising:
a breakdown voltage improvement layer provided between the buffer layer and the drift layer, joined to the drift layer by heterojunction, having a thickness of equal to or greater than 0.5 μm, and made of a fifth group III nitride semiconductor.

14. The nitride semiconductor apparatus according to any of claim 2, further comprising:
a depletion layer formation layer provided between the substrate and the buffer layer and made of a p-type sixth group III nitride semiconductor.

15. The nitride semiconductor apparatus according to any of claim 2, wherein
the source electrode is connected to the substrate.
